(19) United States
(12) Patent Application Publication
(10) Pub. No.: US 2009/0146136 A1
(43) Pub. Date: Jun. 11, 2009

(54) ORGANIC MEMORY DEVICE AND METHOD OF FABRICATING THE SAME

(75) Inventors: Sung Yool CHOI, Daejeon (KR); Sung Soo Bae, Seoul (KR); Hey Jin Myoung, Daejeon (KR)

Correspondence Address: AMPACC LAW GROUP, 13024 Beverly Park Road, Suite 205, Mukilteo, WA, 98275, US

(73) Assignee: Electronics and Telecommunication Research Institute, Daejeon (KR)

(21) Appl. No.: 12/195,289

(22) Filed: Aug. 20, 2008

(30) Foreign Application Priority Data
Dec. 7, 2007 (KR) 2007-126862

(51) Int. Cl. H01L 51/00; H01L 51/40

(52) U.S. Cl. 257/40; 438/99; 257/E51.001; 257/E51.014

(57) ABSTRACT

Provided are a highly integrated organic memory device and a method of fabricating the same. The device includes an insulating substrate, a lower electrode disposed on the insulating substrate, an electron channel layer disposed on the lower electrode, and an upper electrode disposed on the electron channel layer. A bulk heterojunction formed of an electron-donor/electron-acceptor polymer is used as the electron channel layer having electrical bistability. Thus, a highly integrated organic memory device can be formed by a simple fabrication process.

### CROSS-REFERENCE TO RELATED APPLICATION

This application claims priority to and the benefit of Korean Patent Application No. 2007-126862, filed Dec. 7, 2007, the disclosure of which is incorporated herein by reference in its entirety.

### BACKGROUND

1. Field of the Invention

The present invention relates to an organic memory device and a method of fabricating the same and, more particularly, to an organic memory device using a bulk heterojunction formed of organic electron-donor materials and organic electron-acceptor materials as an electron channel layer having electrical bistability and a method of fabricating the same

2. Discussion of Related Art

Globally, semiconductor memory technology has reached a stage of realization of Gbit DRAMs, and it is expected that 100 Gbit integrated circuits (ICs) will be developed in 2010 or thereabouts. With developments in semiconductor devices, the downscaling of the semiconductor devices has led to introduction of ultrahigh-speed, high-capacity, high-integrated, low-power, and high-performance characteristics. As a result, it is expected that system-on-chip (SoC) components essential for ubiquitous communication environments will be provided.

Current commercial nonvolatile memory technology is mostly related to flash memory devices based on charge control of electrons. As design rules have been reduced, the thickness of a tunneling oxide layer of a flash memory had to be also reduced. However, although current flash memories use a CMOS operating voltage, a power of 1.5 to 5V is internally charge-pumped to 17 to 20V in order to enable programming or erasure of data. Accordingly, a breakdown of the tunneling oxide layer due to application of a high voltage has become problematic, thereby degrading reliability of the flash memory.

Since equivalent oxide thickness (EOT) must be considered during design of flash memories, the entire fabrication process becomes very complicated. For sub-65-nm design rules, there is a specific technical limit for scaling down semiconductor devices due to noise between cells so that a lot of doubts are being thrown on the operating feasibility of the semiconductor devices.

Furthermore, it is difficult for current flash memories to have sufficient cell-current device characteristic margins during low-voltage operation, thereby precluding a reduction in power consumption. Accordingly, it is absolutely necessary to develop new memory devices that can overcome the foregoing physical and electrical drawbacks and replace the current flash memories. Therefore, research has lately been conducted on organic memories because it is expected that the organic memories will meet the requirements of nonvolatile memories.

In IEDM 2003, Infineon Technologies AG has reported the structure and device characteristics of a highly integrated nonvolatile memory formed of an organic material except for specific materials of the highly integrated nonvolatile memory. The highly integrated nonvolatile memory is a cross-point 1R memory device in which an organic thin layer is formed between a lower electrode and an upper electrode and a pattern or a dielectric spacer is formed to reduce crosstalk between memory cells. It was reported that the highly integrated nonvolatile memory had an Iₒₙ/I_{off} value of about 10² and a data retention time of about 8 months.

UCLA has taught a nonvolatile organic memory formed of an organic material/metal/organic multiple thin layer, which exhibits electrical bistability. Referring to FIG. 1A, the nonvolatile organic memory disclosed by UCLA includes a multiple structure including a metal electrode 10, an organic material 20, an intermediate metal layer 30, another organic material 20, and another metal electrode 10. The organic materials 20 may be formed of 2-amino-4,5-imidazoledicarbonitrile (AIDCN) shown in FIG. 1B. The metal electrodes 10 and the intermediate metal layer 30 may be formed of Al. As can be seen from FIG. 1C, it was reported that the nonvolatile organic memory had a very high Iₒₙ/I_{off} value of about 10⁴ to 10⁵ and a data retention time of several months.

L. P. Ma et al. have explained in Applied Physics Letters, 82(9), 1419 (2003) that electrical bistability occurs due to a difference in electric conductivity caused by charges stored in nanostructures of an organic material and an intermediate metal layer. In other words, after the intermediate metal layer is deposited to a thickness of 5 to 20 nm, metal nanoparticles form a lump due to heat generated during deposition of the organic material, and it can be expected that the nanoparticles will become a charge storage material. However, since the metal nanoparticles, which are obtained after the deposition of the intermediate metal layer, cannot be uniform, non-uniformity between organic memory devices may be caused due to the shrinkage of the organic memory devices.

Theoretically, since an organic memory device occupies smaller cell area (about 4F²) than the conventional memory devices, the organic memory device have advantage for highly integrated circuits. However, as can be seen from the above-described results of research, thermal and chemical stability of polymer and organic materials are not ensured under the operating conditions of the organic memory device, so that the organic memory device cannot meet the requirements of highly integrated memories. In addition, an organic material has different processibility from conventional inorganic semiconductors. Accordingly, it is necessary to develop process techniques for realizing integration of polymer memories, for example, an organic material patterning technique, an organic material deposition technique, an organic material etching technique, and a low-temperature electrode forming technique.

### SUMMARY OF THE INVENTION

The present invention is directed to an organic memory device, which employs a heterojunction thin layer formed of one of various mixtures of electron-donors and electron-acceptors as an organic material having electrical bistability, and a method of fabricating the same.

One aspect of the present invention provides an organic memory device including: a substrate; a lower electrode disposed on the substrate; an electron channel layer disposed on the lower electrode and formed of an organic mixture of an electron donor and an electron acceptor; and an upper electrode disposed on the electron channel layer.

The organic mixture forming the electron channel layer may be a mixture of P3HT shown in Formula 1 and PCBM shown in Formula 2:

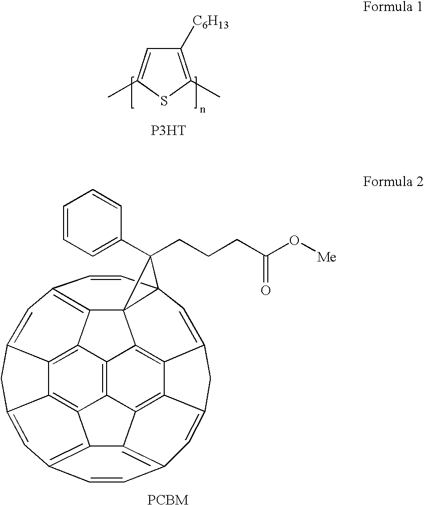

wherein n is an integer ranging from 10 to 10,000. But the electron donor/acceptor combinations can also be used as organic mixtures.

Another aspect of the present invention provides a method of fabricating an organic memory device. The method includes: forming a lower electrode on a substrate; forming an electron channel layer using an organic mixture of an electron donor and an electron acceptor on the lower electrode; and forming an upper electrode on the electron channel layer.

The organic mixture forming the electron channel layer may be a mixture of P3HT shown in Formula 1 and PCBM shown in Formula 2.

The electron channel layer may be formed by spin-coating the organic mixture of the electron donor and the electron acceptor.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1A is a cross-sectional view of a conventional organic memory device;

FIG. 1B is a structural formula of an organic material of an organic layer of the organic memory device shown in FIG. 1A;

FIG. 1C is a graph showing current-voltage (I-V) characteristics of the organic memory device shown in FIG. 1A;

FIG. 2 is a cross-sectional view of an organic memory device according to an exemplary embodiment of the present invention; and

FIG. 3 is a graph showing IV characteristics of an organic memory device according to an exemplary embodiment of the present invention.

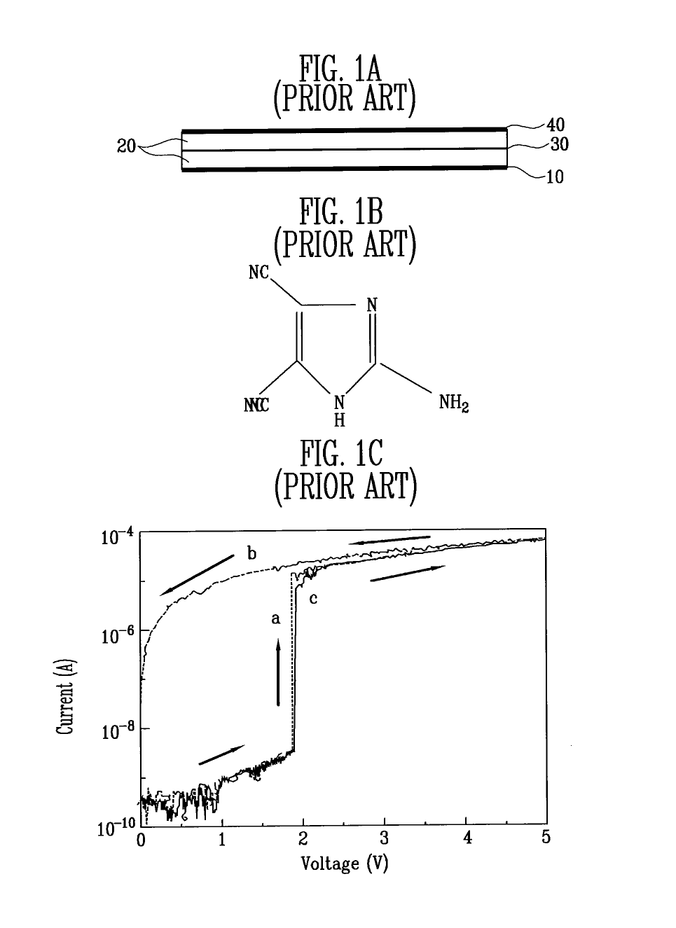

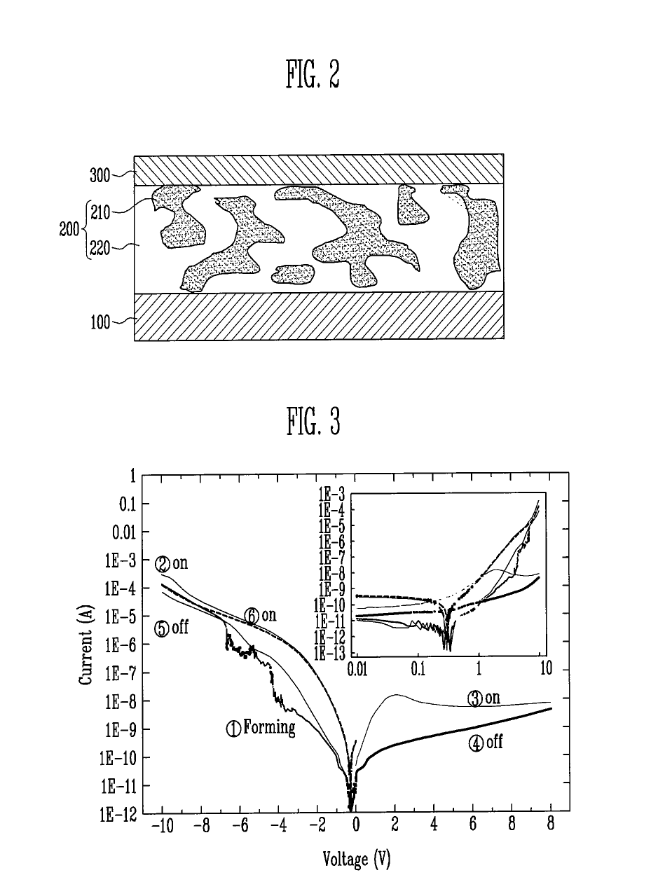

### DETAILED DESCRIPTION OF EMBODIMENTS

Referring to FIG. 2, an organic memory device according to an exemplary embodiment of the present invention includes a lower electrode 100, an electron channel layer 200, and an upper electrode 300, which are sequentially formed on a substrate (not shown). The electron channel layer 200 is a thin layer including a heterojunction of an electron donor 210 and an electron acceptor 220.

The substrate may be an insulating substrate, typically, a silicon substrate. However, the present invention is not limited thereto and a plastic substrate, such as a PES substrate, may be used according to purposes.

The lower electrode 100 and the upper electrode 300 may be formed of a typical electrode material, such as Al, Cu, Au, Pt, indium tin oxide (ITO), or doped silicon.

In order for the organic memory device to perform precise operations, a glue layer (e.g., a Ti layer or a Cr layer) or a monomer layer may be formed between the metal and the organic material to improve contact characteristics between the organic material and the electrodes.

Each of the upper and lower electrodes 300 and 100 may have a width of about 1 nm to 100 μm and include a pad that electrically contacts an external device. Also, each of the upper and lower electrodes 300 and 100 may be obtained using an ordinary pattern forming process, for example, an optical lithography process, an electronic beam (e-beam) lithography process, or a shadow deposition process.

The organic material forming the electron channel layer 200 according to the present invention is formed of an electron-donating organic material and an electron-accepting organic material that can induce electrical bistability.

In the present invention, a mixture of an electron-donating polymer material, such as poly(3-hexylthiophene) (hereinafter, referred to as ‘P3HT’), and an electron-accepting organic material, such as [6,6]-phenyl-C61-butyric acid methyl ester (hereinafter, referred to as ‘PCBM’), is used as an organic semiconductor material.

A predetermined amount of organic mixture may be dissolved in an organic solvent, mixed in solution states, and coated on the lower electrode 100 using a spin coating process. The resulting organic thin layer may have a thickness of about 3 to 200 nm and must have a uniformity of 5% or less with respect to the thickness.

The upper electrode 300 is deposited on the organic thin layer (i.e., the electron channel layer 200), thereby completing the fabrication of the organic memory device according to the present invention.

Diclorobenzene (DCB) or trichlorobenzene (TCB) may be used as the solvent of the organic material. Each of the electron donor and the electron acceptor may be contained in the organic solvent at a concentration of about 0.01 to 10.0 wt. %. Each of the electron donor and the electron acceptor is dissolved in the organic solvent at a predetermined concentration, and the electron donor and the electron acceptor are mixed in a predetermined ratio to form an organic mixture. In this case, the electron donor and the electron acceptor may be mixed at a concentration ratio of 1:10 to 10:1 (electron donor:electron acceptor). In order to maximize the effects of the organic memory device, the electron donor and the electron acceptor may be mixed at a concentration ratio of 1:1 to 2:1.

As shown in FIG. 2, when a voltage is applied to the upper and lower electrodes 300 and 100, current may flow through the upper and lower electrodes 300 and 100 in predetermined directions. Also, the organic memory device according to the present invention can have a high conductivity (hereinafter, referred to as ‘on state’) 700 and a low conductivity (hereinafter, referred to as ‘off state’) 800 so as to exhibit a memory effect. When an applied voltage is increased from 0 V to a threshold voltage Vt, the organic memory device operates in the off state. However, when the applied voltage exceeds the threshold voltage Vt, the organic memory device is sent to the on state. In other words, when a voltage higher than the threshold voltage Vt is applied, the electron channel layer 200 is shifted to the on state. A reverse voltage must be applied in order to convert the on state into the off state. That is, a negative threshold voltage −Vt is applied to shift the electron channel layer 200 from the on state to the off state. The foregoing process may be repeated. Since each conductivity is maintained for a predetermined time or longer, the organic memory device according to the present invention can be employed as a nonvolatile memory device.

In order to allow abrupt reversible phase transition between the on state and the off state, the organic material forming the electron channel layer 200 must have a semiconductor characteristic or insulation characteristic (i.e., a bandgap of 2 eV or higher), and a threshold voltage Vt of 0.5 eV or higher is required between the organic material and the upper and lower electrodes 300 and 100.

### Embodiment 1

A 150-nm thick ITO thin layer was formed on a glass substrate, and a 40-μm wide lower electrode was formed using a lithography process. 8 mg P3HT was dissolved in 1 ml DCB, 8 mg PCBM was dissolved in 1 ml DCB, and a P3HT solution and a PCBM solution are mixed in a ratio of 1:1. The mixture was spin-coated on the lower electrode, thereby forming an electron channel layer to a thickness of about 100 nm or less. Thereafter, an Al upper electrode was deposited on the electron channel layer to a thickness of about 60 nm or less, thereby completing the fabrication of an organic memory device.

The current-voltage (I-V) characteristics of the organic semiconductor layer having the Al/P3HT+PCBM/ITO structure were measured as shown in FIG. 3.

Referring to FIG. 3, the organic semiconductor layer exhibits two different electrical conductivities at the same voltage. However, it can be observed that the organic memory device generally showed a large variation in current. During an initial bias scan (refer to Curve 1), the flow of a small current was confirmed in the voltage range of 0 V to −4.0 V. However, a current was sharply increased from 5×10⁻⁸ to 5×10⁻⁵ A at a voltage of about −4.0 V. Therefore, it can be seen that when an applied voltage reached a predetermined reset voltage, the transition from an off state to an on state was made. After the transition was made, the organic memory device remained in the on state during a continuous bias scan (refer to Curve 2). In this case, it can be confirmed that the conductivity of the on-state organic memory device is 10³ higher than that of the off-state organic memory device.

In an organic memory device according to the present invention, the characteristics of a channel can switch between an on state and an off state according to an external applied voltage. Also, non-uniformity between devices caused by the downscaling of the devices can be solved using uniform nanoparticles, thereby improving the characteristics of the organic memory device.

Also, the non-uniformity between devices caused by the downscaling of the devices can be solved by using a thin layer formed of a uniform organic mixture other than a layer formed of a conventional organic material/metal nanoparticle layer/organic material.

In the drawings and specification, there have been disclosed typical preferred embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. An organic memory device comprising:
a substrate;
a lower electrode disposed on the substrate;
an electron channel layer disposed on the lower electrode and formed of an organic mixture of an electron donor and an electron acceptor; and
an upper electrode disposed on the electron channel layer.

2. The device according to claim 1, wherein the organic mixture forming the electron channel layer is a mixture of P3HT shown in Formula 1 and PCBM shown in Formula 2: 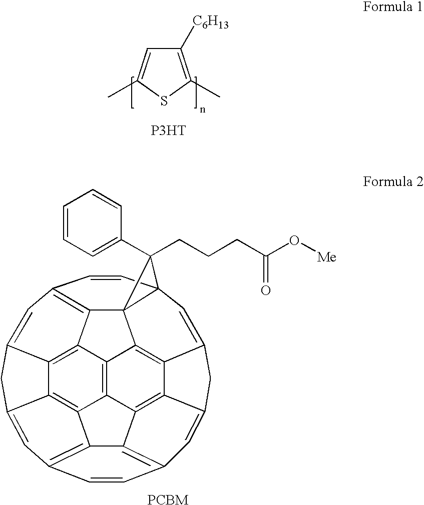
wherein n is an integer ranging from 10 to 10,000.

3. The device according to claim 2, wherein P3HT and PCBM are mixed at a concentration ratio of 10:1 to 1:10.

4. The device according to claim 1, wherein the electron channel layer has a thickness of about 5 to 200 nm.

5. A method of fabricating an organic memory device, comprising:
forming a lower electrode on a substrate;
forming an electron channel layer using an organic mixture of an electron donor and an electron acceptor on the lower electrode; and
forming an upper electrode on the electron channel layer.

6. The method according to claim 5, wherein the organic mixture forming the electron channel layer is a mixture of P3HT shown in Formula 1 and PCBM shown in Formula 2: 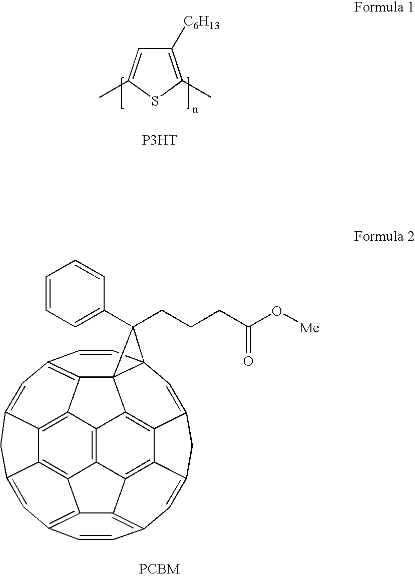
wherein n is an integer ranging from 10 to 10,000.

7. The method according to claim 5, wherein the electron channel layer is formed by spin-coating the organic mixture of the electron donor and the electron acceptor.

8. The method according to claim 7, wherein each of the electron donor and the electron acceptor is contained at a concentration of 0.01 to 10.0 wt. % in dichlorobenzene (DCB) or trichlorobenzene (TCB).
